(19) United States
(12) Patent Application Publication
(10) Pub. No.: US 2026/0221165 A1
(43) Pub. Date: Jul. 30, 2026

(54) SEMICONDUCTOR DEVICE

(71) Applicant: SAMSUNG ELECTRONICS CO., LTD., Suwon-si (KR)

(72) Inventors: Kiseok LEE, Suwon-si (KR); Jinwoo HAN, Suwon-si (KR); Minsoo KIM, Suwon-si (KR)

(73) Assignee: SAMSUNG ELECTRONICS CO., LTD., Suwon-si (KR)

(21) Appl. No.: 19/282,618

(22) Filed: Jul. 28, 2025

(30) Foreign Application Priority Data
Jan. 24, 2025 (KR) 10-2025-0011026

(51) Int. Cl. G11C 5/06; G11C 11/408; G11C 11/4091; G11C 11/4093; G11C 11/419; H01L 23/00; H10B 10/00; H10B 12/00; H10B 80/00; H10D 80/30

(52) U.S. Cl. CPC G11C 5/063; G11C 11/4087; G11C 11/4091; G11C 11/4093; G11C 11/419; H10B 10/12; H10B 10/18; H10B 12/315; H10B 12/485; H10B 12/488; H10B 12/50; H10B 80/00; H10D 80/30; H10W 90/792

(57) ABSTRACT

A semiconductor device includes a first layer including memory cells connected to bitlines and wordlines, where each of the memory cells includes a cell transistor and a cell capacitor, a second layer on the first layer and including a row decoder connected to the wordlines, a sense amplifier circuit connected to the bitlines, and a column decoder configured to determine a select bitline among the bitlines, and a third layer on the second layer, the third layer including a logic circuit configured to control the row decoder, the sense amplifier circuit, and the column decoder and an input/output interface configured to transmit a signal to and receive a signal from an external device, where the second layer includes a computation circuit configured to execute at least one computation based on at least one of input data received by the input/output interface and read data read from the memory cells.

### CROSS-REFERENCE TO RELATED APPLICATION(S)

This application is based on and claims priority to Korean Patent Application No. 10-2025-0011026, filed on Jan. 24, 2025, in the Korean Intellectual Property Office, the disclosure of which is incorporated by reference herein in its entirety.

### BACKGROUND

The present disclosure relates to a semiconductor device.

A dynamic random access memory (DRAM) device may be a semiconductor device which may store data, and may be applied to various fields due to a high response speed. A semiconductor device may include memory cells in which data is recorded, and various circuits driving the memory cells, and recently, in addition to a function of simply storing data, circuits which may perform computations have been added to a semiconductor device. However, considering integration density of a semiconductor device, there may be a limitation in disposing a computation circuit in a semiconductor device.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device which may be capable of implementing process-in-memory (PIM), process-near-memory (PNM), and in-memory-computing (IMC) by stacking a cell region in which memory cells are disposed, a core region in which circuits driving the memory cells are disposed, and a peripheral circuit region in which input/output interfaces and logic circuits are disposed.

Additional aspects will be set forth in part in the description which follows and, in part, will be apparent from the description, or may be learned by practice of the presented embodiments.

According to an aspect of one or more embodiments, a semiconductor device may include a first layer including memory cells connected to bitlines and wordlines, where each of the memory cells includes a cell transistor and a cell capacitor, a second layer on the first layer, the second layer including a row decoder connected to the wordlines, a sense amplifier circuit connected to the bitlines, and a column decoder configured to determine a select bitline among the bitlines, and a third layer on the second layer, the third layer including a logic circuit configured to control the row decoder, the sense amplifier circuit, and the column decoder and an input/output interface configured to transmit a signal to and receive a signal from an external device, where the second layer includes a computation circuit configured to execute at least one computation based on at least one of input data received by the input/output interface and read data read from the memory cells.

According to an aspect of one or more embodiments, a semiconductor device may include a first layer including memory cells connected to bitlines and wordlines, a second layer including a sub-wordline decoder connected to the wordlines, a sense amplifier circuit connected to the bitlines, and a column decoder configured to determine a select bitline among the bitlines, and a third layer including a peripheral circuit configured to control the sense amplifier circuit and the column decoder, where the first layer, the second layer, and the third layer are stacked sequentially in a first direction, the second layer includes a computation circuit configured to execute computation using read data read from the memory cells, the bitlines extend in a second direction perpendicular to the first direction, and the wordlines extend in a third direction perpendicular to the first direction and the second direction, and the computation circuit is adjacent to the sense amplifier circuit in the second direction, and adjacent to the sub-wordline decoder in the third direction.

According to an aspect of one or more embodiments, a semiconductor device may include a first layer including memory cells, a second layer coupled to the first layer on a first boundary, the second layer including a core circuit configured to control the memory cells, and a third layer coupled to the second layer on a second boundary, the third layer including a peripheral circuit configured to control the core circuit, where a first bonding insulating layer in the first layer is coupled to a second bonding insulating layer in the second layer on the first boundary, a third bonding insulating layer in the second layer is coupled to a fourth bonding insulating layer in the third layer on the second boundary, the first boundary has one of a first bonding structure in which interconnections opposing each other are coupled to and electrically connected to each other, and a second bonding structure in which at least one via structure penetrates the first bonding insulating layer and the second bonding insulating layer, and the second boundary has one of the first bonding structure and the second bonding structure.

### BRIEF DESCRIPTION OF DRAWINGS

The above and other aspects, features, and advantages of certain one or more embodiments of the present disclosure will be more apparent from the following description taken in conjunction with the accompanying drawings, in which:

FIGS. 1 and 2 are diagrams illustrating a semiconductor device according to one or more embodiments;

FIG. 3 is a diagram illustrating a stack structure of a semiconductor device according to one or more embodiments;

FIGS. 4, 5, 6, 7 and 8 are diagrams illustrating a structure of a semiconductor device according to one or more embodiments;

FIGS. 9, 10, 11 and 12 are diagrams illustrating a bonding structure of layers included in a semiconductor device according to one or more embodiments;

FIGS. 13, 14, 15 and 16 are diagrams illustrating a structure of a semiconductor device according to one or more embodiments;

FIG. 17 is a diagram illustrating a system including a semiconductor device according to one or more embodiments;

FIGS. 18, 19, 20 and 21 are diagrams illustrating a stack structure of semiconductor devices according to one or more embodiments; and

FIGS. 22 and 23 are diagrams illustrating a structure of a core region included in a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

In addition, terms such as “unit” and “module” described in the specification may indicate a unit that processes at least one function or operation, and this may be implemented as hardware or software, or may be implemented as a combination of hardware and software.

The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

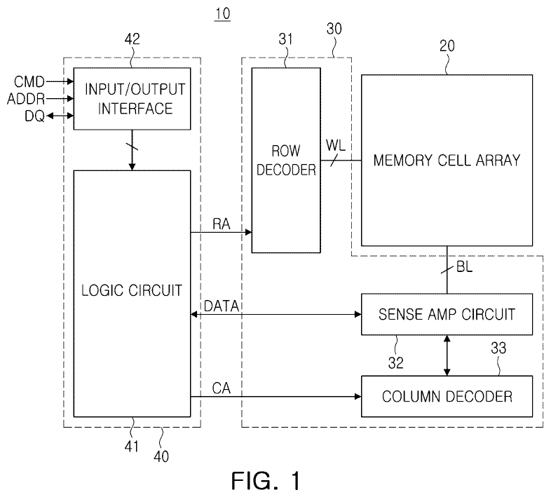

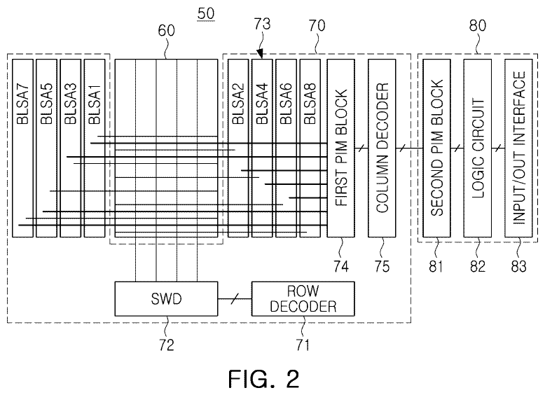

FIGS. 1 and 2 are diagrams illustrating a semiconductor device according to one or more embodiments.

Referring to FIG. 1, a semiconductor device 10 according to one or more embodiments may include a memory cell array 20, a core circuit 30, and a peripheral circuit 40. In one or more embodiments, the core circuit 30 may include a row decoder 31, a sense amplifier circuit 32, and a column decoder 33, and the peripheral circuit 40 may include a logic circuit 41 and an input/output interface 42.

The memory cell array 20 may include a plurality of memory cells. The plurality of memory cells may be connected to the row decoder 31 through a plurality of wordlines WL and may be connected to the sense amplifier circuit 32 through a plurality of bitlines BL. The plurality of memory cells may be positioned at points at which the plurality of wordlines WL and the plurality of bitlines BL intersect each other. The plurality of memory cells may be disposed in a matrix form in the memory cell array 20, and each of the plurality of memory cells may include at least one memory element for storing data. For example, each of the plurality of memory cells may include a cell transistor configured to operate as a switch, and a cell capacitor configured to store data by charging and discharging electric charges.

Operation of the core circuit 30 may be controlled by the peripheral circuit 40. For example, the input/output interface 42 may receive a control command CMD, an address signal ADDR and a data signal DQ from an external host, or the like. The address signal ADDR may include a row address RA indicating a row in the memory cell array 20 and a column address CA indicating a column in the memory cell array 20. The logic circuit 41 may determine a select wordline from among a plurality of wordlines WL by controlling the row decoder 31 based on the row address RA, and may determine a select bitline from among a plurality of bitlines BL by controlling the column decoder 33 based on the column address CA.

The sense amplifier circuit 32 may include a plurality of bitline sense amplifiers connected to the memory cell array 20 through a plurality of bitlines. For example, when a read operation is executed, the bitline amplifier connected to the select bitline selected by the column decoder 33 may read data DATA stored in the memory cell connected to the select wordline selected by the row decoder 31. The logic circuit 41 may serialize the data DATA read from the select memory cells and may output the data as a data signal DQ.

The data stored in the semiconductor device 10 may be used by an external host to perform various computations. However, for computations such as AI computation, a large amount of data may be required, and accordingly, when a data transmission speed and a bandwidth of the input/output interface 42 are not sufficiently ensured, a computation speed may be reduced. To address this, a method of implementing a circuit configured to perform computation in the semiconductor device 10 has been suggested, but the method may lead to a decrease in integration density of the semiconductor device 10.

In one or more embodiments, a semiconductor device 10 may be manufactured by forming a memory cell array 20, a core circuit 30, and a peripheral circuit 40 on different wafers and stacking the circuits. A semiconductor device 10 may include a first layer in which the memory cell array 20 is disposed, a second layer in which the core circuit 30 is disposed, and a third layer in which the peripheral circuit 40 is disposed, and the first to third layers may be stacked.

Since the memory cell array 20 may occupy a relatively larger area than the core circuit 30 and the peripheral circuit 40, a computation circuit configured to perform computation in at least one free area of the second layer on which the core circuit 30 is disposed and the third layer, on which the peripheral circuit 40 is disposed, may be disposed. Accordingly, a computation requiring a large amount of data, for example, an AI computation, may be executed in the semiconductor device 10, and a semiconductor device 10 optimized for a computation using a large amount of data may be implemented despite limitations in a data transmission speed and a bandwidth of the input/output interface 42.

Referring to FIG. 2, a semiconductor device 50 according to one or more embodiments may include a cell region 60, a core region 70, and a peripheral circuit region 80. The memory cells may be disposed in the form of a memory cell array in the cell region 60. In the core region 70, a row decoder 71, a sub-wordline decoder 72, bitline sense amplifiers 73, a first process in memory (PIM) block 74, and a column decoder 75 configured to control the cell region 60 may be disposed. In the peripheral circuit region 80, a second PIM block 81, a logic circuit 82, and an input/output interface 83 may be disposed.

As described with reference to FIG. 1, the logic circuit 82 may store data in the cell region 60 or may read data stored in the cell region 60 by controlling the core region 70 based on a command signal and an address signal received by the input/output interface 83. The cell region 60, the core region 70, and the peripheral circuit region 80 may be implemented on different layers, and the layers may be stacked and may provide a semiconductor device 50.

In a structure in which the semiconductor device 50 does not include the PIM blocks 74 and 81, the cell region 60 may occupy a relatively large area as compared to each of the core region 70 and the peripheral circuit region 80. Accordingly, by implementing the cell region 60, the core region 70, and the peripheral circuit region 80 as separate layers, free areas may be ensured in the layer on which the core region 70 is implemented, and the layer on which the peripheral circuit region 80 is implemented.

In the free area ensured in each layer, the first PIM block 74 and the second PIM block 81 may be disposed. Each of the first PIM block 74 and the second PIM block 81 may include a computation circuit for performing a predetermined computation. For example, a circuit for performing a multiply and accumulate (MAC) computation necessary for implementing an AI function may be disposed in at least one of the first PIM block 74 and the second PIM block 81. In one or more embodiments, the second PIM block 81 disposed in the peripheral circuit region 80 may include a static random access memory (SRAM) cell array which may operate as a cache memory, and a computation circuit for performing parallel computation. Accordingly, in-memory computing may be efficiently implemented, and various computations using data stored in the semiconductor device 50 may reduce an increase in data transfer between the semiconductor device 50 and an external host and may be swiftly and efficiently performed.

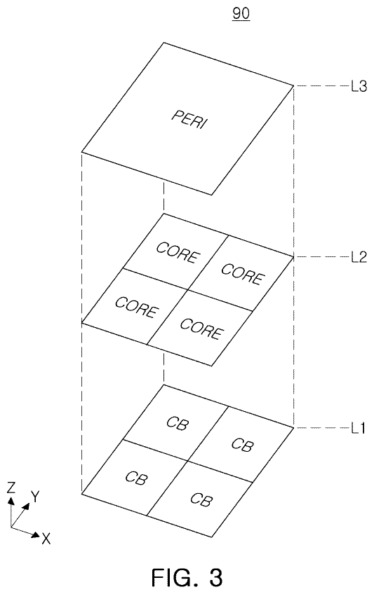

FIG. 3 is a diagram illustrating a stack structure of a semiconductor device according to one or more embodiments.

Referring to FIG. 3, a semiconductor device 90 according to one or more embodiments may include a plurality of layers L1-L3 stacked in a first direction (Z-axis direction). A plurality of cell blocks CB may be disposed in a first layer L1, a plurality of core circuits CORE may be disposed in a second layer L2, and a peripheral circuit PERI may be disposed in a third layer L3. For example, a cell block CB and a core circuit CORE disposed in the same position in the second direction (X-axis direction) and the third direction (Y-axis direction) may provide a memory bank. The peripheral circuit PERI may control a plurality of memory banks provided by the first layer L1 and the second layer L2.

For example, each of the plurality of layers L1-L3 may be configured as a semiconductor die manufactured from a different wafer. By manufacturing the plurality of layers L1-L3 from different wafers and stacking the plurality of layers L1-L3 in a wafer-to-wafer, wafer-to-die, and die-to-die manner, a semiconductor device 90 may be manufactured.

For example, pads required for the semiconductor device 90 to transmit signals to and receive signals from other external devices may be included in the third layer L3, which may be because an input/output interface may be implemented in the peripheral circuit PERI of the third layer L3. The peripheral circuit PERI may control the core circuit CORE in response to a signal received through the pads, and the core circuit CORE may write data to memory cells disposed in the cell blocks CB or may read data written to the memory cells according to a command of the peripheral circuit PERI.

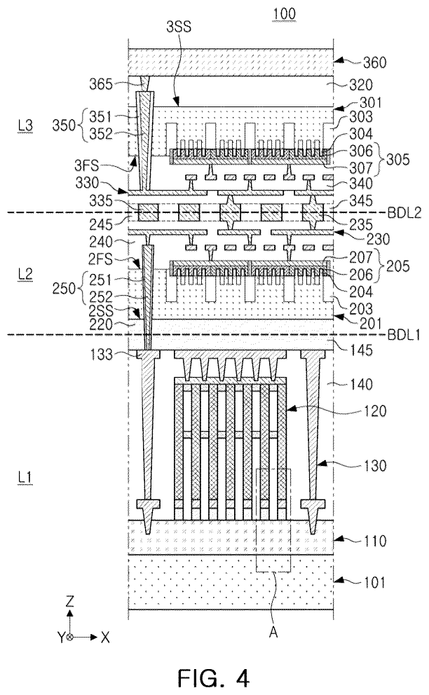

Each of the plurality of layers L1-L3 may include a substrate, and the stack structure of the plurality of layers L1-L3 may be variously determined in one or more embodiments. For example, the first layer L1 may include a first substrate, the second layer L2 may include a second substrate, and the third layer L3 may include a third substrate. The second layer L2 may include a plurality of elements formed on a first surface 2FS of the second substrate, and the second layer L2 may be disposed such that the first surface 2FS of the second substrate may face the first layer L1 or may face the third layer L3. The third layer L3 may include a plurality of elements formed on the first surface 3FS of the third substrate, and the third layer L3 may be disposed such that the first surface 3FS of the third substrate may face the second layer L2 or may face pads. Hereinafter, the stack structure of layers L1-L3 included in the semiconductor device 90 will be described in greater detail with reference to FIGS. 4 to 8.

FIGS. 4, 5, 6, 7 and 8 are diagrams illustrating a structure of a semiconductor device according to one or more embodiments.

Referring to FIG. 4, a semiconductor device 100 according to one or more embodiments may include a plurality of layers L1-L3 stacked in a first direction (Z-axis direction). A first boundary BDL1 may be defined between a first layer L1 and a second layer L2, and a second boundary BDL2 may be defined between the second layer L2 and a third layer L3.

The first layer L1 may provide a cell region in which a plurality of memory cells are disposed. For example, the first layer L1 may include a first substrate 101, a first element region 110, capacitor structures 120, first interconnection patterns 130, and a first interlayer insulating layer 140. The first element region 110 may be defined on a first surface of the first substrate 101, and a cell transistor included in each of the memory cells may be implemented in the first element region 110. In one or more embodiments, the cell transistor may be formed as a structure buried in the first substrate 101.

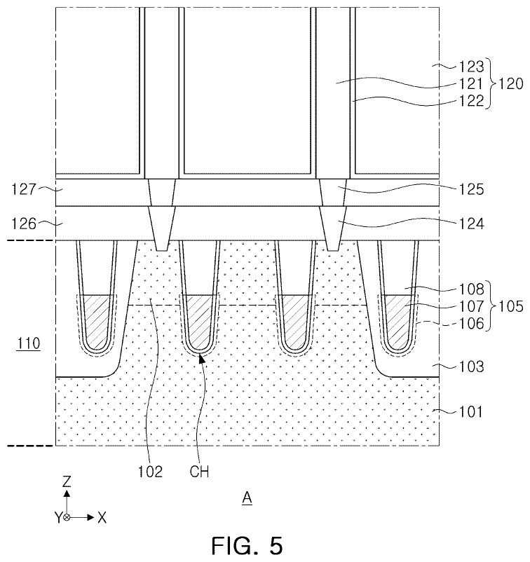

Cell transistors disposed in the first element region 110 may be connected to the capacitor structures 120 implemented on the first element region 110 and may provide memory cells. The structure of the first element region 110 and the capacitor structures 120 will be described in greater detail with reference to FIG. 5, which is an enlarged diagram illustrating region ‘A’ in FIG. 4.

Referring to FIG. 5, the first element region 110 may include a plurality of gate structures 105 and an element separator 103 buried in the first substrate 101. The plurality of gate structures 105 may be disposed in a predetermined direction, for example, a second direction (X-axis direction), may extend in a third direction (Y-axis direction), and may include a gate insulating layer 106, a gate electrode layer 107, and a gate capping layer 108. Each of the plurality of gate structures 105 may provide a wordline structure and may be electrically connected to a sub-wordline decoder of the core circuit.

In one or more embodiments, the gate electrode layer 107 may have a multilayer structure formed of a plurality of different conductive materials, for example, metal materials, and may provide wordlines. The gate capping layer 108 may be formed of polysilicon, silicon nitride, silicon oxide, silicon oxynitride, silicon carbonitride, silicon oxycarbonitride, or the like.

As illustrated in the example in FIG. 5, a channel region CH may be formed in a region adjacent to each of the gate electrode layers 107 of the plurality of gate structures 105. An active region 102 may be formed between the plurality of gate structures 105 in the second direction, and for example, the active region may be defined in a region in which the element separator 103 is not formed. The active region 102 may provide a source region and a drain region of the cell transistor.

Capacitor structures 120 may be formed on the first substrate 101. For example, lower interlayer insulating layers 126 and 127 may be disposed on the first substrate 101, and lower contact structures 124 and 125 penetrating the lower interlayer insulating layers 126 and 127 may be formed. The lower contact structures 124 and 125 may be connected between the active region 102 and the capacitor structures 120.

Among the active regions 102, the active region 102 not connected to the capacitor structures 120 may be connected to a bitline structure formed in the lower interlayer insulating layers 126 and 127. The bitline structure may extend in the second direction and may be electrically connected to a sense amplifier circuit of the core circuit.

Each of the capacitor structures 120 may include a capacitor dielectric layer 121, a lower electrode layer 122, and an upper electrode layer 123, and the capacitor dielectric layer 121 may be disposed between the lower electrode layer 122 and the upper electrode layer 123. The lower electrode layer 122 may be modified to have a shape other than a pillar shape as illustrated in the example in FIG. 5. Each of the lower electrode layer 122 and the upper electrode layer 123 may be formed of a conductive material, for example, a metal, a metal compound, or the like, and in one or more embodiments, the upper electrode layer 123 may be formed of a doped semiconductor material.

However, the structure of the cell transistors and the capacitor structures 120 is not necessarily limited to the example illustrated in FIG. 5. For example, the cell transistors may be implemented as a structure other than a buried transistor as illustrated in the example in FIG. 5, such as a vertical channel transistor. Also, the cell region may be implemented as a three dimensional structure in which the cell transistors and capacitor structures 120 are connected to each other in a direction parallel to the first surface of the first substrate 101, rather than in the first direction.

Referring back to FIG. 4, the first interconnection patterns 130 on the first layer L1 may be disposed in the first interlayer insulating layer 140, and may be formed of a conductive material such as a metal or a metal compound. The first interlayer insulating layer 140 may be formed of silicon oxide, silicon nitride, silicon oxynitride, or the like. As illustrated in FIG. 4, the first bonding insulating layer 145 may be disposed in a region in vicinity of the first boundary BDL1 on the first layer L1. In FIG. 4, the first bonding insulating layer 145 may be bonded to the second lower bonding insulating layer 220 included in the second layer L2. For example, each of the first bonding insulating layer 145 and the second lower bonding insulating layer 220 may include silicon oxide, silicon carbonitride, or the like.

First uppermost interconnections positioned on an uppermost layer among the first interconnection patterns 130 may be disposed in a lower portion of the first bonding insulating layer 145. For example, the first uppermost interconnections may be interconnections positioned farthest from the first substrate 101 among the first interconnection patterns 130, and may be interconnections positioned closest to the second layer L2 among the first interconnection patterns 130. The first uppermost interconnections may provide at least one landing pad 133, and the landing pad 133 may be connected to a second via structure 250 extending from the second layer L2 and penetrating the first bonding insulating layer 145 and the second lower bonding insulating layer 220.

The second layer L2 may provide a core region in which a row decoder, a sense amplifier circuit, and a column decoder which may control a plurality of memory cells are disposed. For example, the second layer L2 may include a second substrate 201, a plurality of elements providing a core region, a second interconnection patterns 230, and a second interlayer insulating layer 240. A plurality of fin structures 204 protruding in the first direction may be formed on a first surface 2FS of the second substrate 201, and the plurality of fin structures 204 may provide a channel region. An element separator 203 may be formed between the plurality of fin structures 204 using an insulating material such as silicon oxide.

In the third direction, a source region and a drain region may be formed on both sides of the plurality of fin structures 204, and a plurality of gate structures 205 may be formed in a structure passing over the plurality of fin structures 204. The plurality of gate structures 205 may include a gate insulating layer 206 and a gate electrode layer 207. In one or more embodiments, a plurality of elements providing a core region may be implemented as a horizontal transistor, a vertical transistor, a multi-bridge channel field effect transistor (FET) (MBCFET™), or the like, rather than the FinFET illustrated in FIG. 4.

The second interconnection patterns 230 of the second layer L2 may be disposed in the second interlayer insulating layer 240 and may be formed of a conductive material such as a metal or a metal compound. The second interconnection patterns 230 and the second interlayer insulating layer 240 may provide a second upper interconnection region defined on the first surface 2FS of the second substrate 201. The second interlayer insulating layer 240 may be formed of silicon oxide, silicon nitride, silicon oxynitride, or the like. The second interlayer insulating layer 240 may be disposed on the first surface 2FS of the second substrate 201, and the second lower bonding insulating layer 220 described above may be disposed on the second surface opposing the first surface 2FS of the second substrate 201.

As illustrated in the example in FIG. 4, a second upper bonding insulating layer 245 may be disposed in a region in vicinity of the second boundary BDL2 on the second layer L2. The second upper bonding insulating layer 245 may be bonded to a third upper bonding insulating layer 345 included in the third layer L3, and each of the second upper bonding insulating layer 245 and the third upper bonding insulating layer 345 may be formed of silicon oxide, silicon carbonitride, or the like.

The second interconnection patterns 230 of the second layer L2 may include a second uppermost interconnection 235 disposed closest to the second boundary BDL2. For example, the second uppermost interconnection 235 may be configured as an interconnection positioned closest to the third layer L3 among the second interconnection patterns 230 in the first direction, and may be an interconnection positioned farthest from the first surface 2FS of the second substrate 201. The second uppermost interconnection 235 may be bonded to the third uppermost upper interconnection 335 included in the third layer L3 at a second boundary BDL2. The third uppermost upper interconnection 335 may refer to an interconnection disposed in the furthest position in the first direction from the first surface 3FS of the third substrate 301 among the third upper interconnection patterns 330. The third uppermost upper interconnection 335 may be an interconnection positioned closest to the second layer L2 among the third upper interconnection patterns 330.

For example, the structure in which the second layer L2 and the third layer L3 are bonded to each other in the second boundary BDL2 may be defined as hybrid bonding. In the semiconductor device 100 in FIG. 4, the bonding structure of the first layer L1 and the second layer L2 may be different from the bonding structure of the second layer L2 and the third layer L3. For example, the bonding structure of the second boundary BDL2 may be defined as fusion bonding.

A portion of the second interconnection patterns 230 may be electrically connected to the second via structure 250 described above. The second via structure 250 may penetrate the second substrate 201, the second lower bonding insulating layer 220, and the first bonding insulating layer 145 of the first layer L1, and may be connected to the landing pad 133 of the first layer L1. The second via structure 250 may include a via insulating layer 251 and a via conductive layer 252, and may be electrically isolated from the second substrate 201 by the via insulating layer 251. The cell region of the first layer L1 and the core region of the second layer L2 may be electrically connected to each other through the second via structure 250.

The third layer L3 may provide a peripheral circuit region in which an input/output interface, a logic circuit, or the like, are disposed. For example, the third layer L3 may include a third substrate 301, a plurality of elements providing a peripheral circuit region, third upper interconnection patterns 330, and a third upper interlayer insulating layer 340. When each of the plurality of elements is configured as a FinFET, a plurality of fin structures 304 protruding in the first direction and providing a channel region may be formed on the first surface 3FS of the third substrate 301.

Similar to the second layer L2, source regions and drain regions may be formed on both sides of the plurality of fin structures 304 in the third direction, and a plurality of gate structures 305 may be formed as a structure passing over the plurality of fin structures 304. The plurality of gate structures 305 may include a gate insulating layer 306 and a gate electrode layer 307. In one or more embodiments, a plurality of elements providing a peripheral circuit region may be implemented as a horizontal transistor, a vertical transistor, an MBCFET™, or the like.

The third upper interconnection patterns 330 of the third layer L3 may be disposed in the third upper interlayer insulating layer 340 and may be formed of a conductive material such as a metal or a metal compound. The third upper interconnection patterns 330 and the third upper interlayer insulating layer 340 may provide a third upper interconnection region defined on the first surface of the second substrate 201. The third upper interlayer insulating layer 340 may be formed of silicon oxide, silicon nitride, silicon oxynitride, or the like. The third upper interlayer insulating layer 340 may be disposed on a first surface 3FS of the third substrate 301, and a third lower interlayer insulating layer 320 may be disposed on a second surface opposing the first surface 3FS of the third substrate 301.

A plurality of pads 360 may be formed on the third lower interlayer insulating layer 320. The plurality of pads 360 may be connected to the pad via 365 and the third via structure 350. The third via structure 350 may penetrate the third substrate 301, may be connected to the third upper interconnection patterns 330, and may include the via insulating layer 351 and the via conductive layer 352. Accordingly, the third via structure 350 may be electrically isolated from the third substrate 301.

The plurality of pads 360 may be connected to input/output interfaces among peripheral circuits disposed in the third layer L3. The semiconductor device 100 may operate based on signals transmitted to and received from an external device through the plurality of pads 360.

As illustrated in FIG. 4, a third upper bonding insulating layer 345 may be disposed in a region in a vicinity of the second boundary BDL2 in the third layer L3. The third upper bonding insulating layer 345 may be bonded to the second upper bonding insulating layer 245 included in the second layer L2. Also, the third uppermost upper interconnection 335 may be bonded to the second uppermost interconnection 235 in the second boundary BDL2. Each of the second upper bonding insulating layer 245 and the third upper bonding insulating layer 345 may be formed of silicon oxide, silicon carbon nitride, or the like, and the structure in which the second layer L2 and the third layer L3 are bonded to each other in the second boundary BDL2 may be defined as hybrid bonding.

Referring to FIG. 4, a pair of bonding insulating layers 145 and 220 in the first boundary BDL1 may be coupled to each other, and a pair of bonding insulating layers 245 and 345 in the second boundary BDL2 may be coupled to each other. Also, the first boundary BDL1 may have a bonding structure in which at least one second via structure 250 penetrates a pair of bonding insulating layers 145 and 220, and the second boundary BDL2 may have a bonding structure in which uppermost interconnections 235 and 335 are coupled to each other in addition to the pair of bonding insulating layers 245 and 345.

As described above, each of the core region and the peripheral circuit region may be implemented in a relatively small area as compared to the cell region. Accordingly, as in the example illustrated in FIG. 4, in a structure in which the cell region, the core region, and the peripheral circuit region may be formed in the first to third layers L1-L3 and the first to third layers L1-L3 may be stacked, a remaining free area may be present in at least one of the second layer L2 and the third layer L3. In one or more embodiments, a computation circuit for supporting PIM, IMC, or the like, may be disposed in at least one free area of the second layer L2 and the third layer L3. For example, the computation circuit may execute a computation using at least one of read data read from the memory cells by the core region and input data received by the input/output interface disposed in the third layer L3.

Referring to FIGS. 4 and 5, in the first layer L1, the gate structure 105, the channel region CH and the active region 102 may provide a cell transistor, and the capacitor structure 120 and the cell transistor may provide a memory cell. In the second layer L2, a source region and a drain region may be formed on both sides of the plurality of fin structures 204 and the source region, the drain region and the plurality of gate structures 205 may provide a plurality of elements of a row decoder, a sense amplifier circuit, a column decoder and the computation circuit. In the third layer L3, a source region and a drain region may be formed on both sides of the plurality of fin structures 304 and the source region, the drain region and the plurality of gate structures 305 may provide a plurality of elements of the logic circuit and the input/output interface.

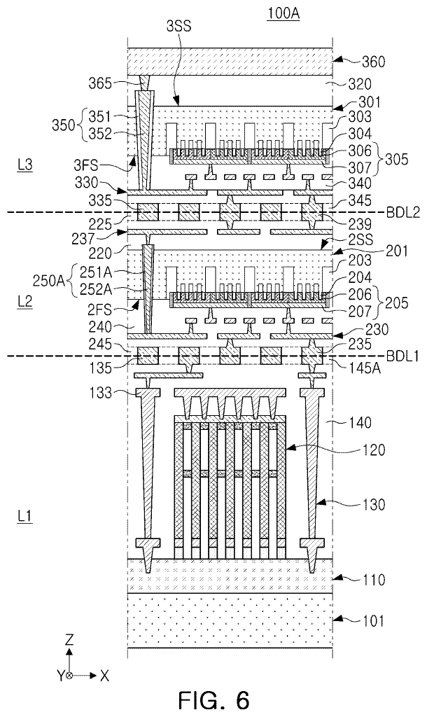

Referring to FIG. 6, a semiconductor device 100A according to one or more embodiments may include a plurality of layers stacked in the first direction, a first boundary BDL1 may be defined between a first layer L1 and a second layer L2, and a second boundary BDL2 may be defined between the second layer L2 and a third layer L3. The first layer L1 may provide a cell region in which a plurality of memory cells are disposed, the second layer L2 may provide a core region in which a row decoder, a sense amplifier circuit, a column decoder, or the like, are disposed, and the third layer L3 may provide a peripheral circuit region in which an input/output interface, a logic circuit, or the like, are disposed.

The first layer L1 may include a first substrate 101, a first element region 110, capacitor structures 120, first interconnection patterns 130, and a first interlayer insulating layer 140. In the first element region 110, cell transistors may be formed, and the cell transistors and capacitor structures 120 may have a structure similar to that described with reference to FIGS. 4 and 5 above. In one or more embodiments, the cell transistors may have a vertical channel transistor structure rather than a buried transistor, and the cell transistors and capacitor structures 120 may be connected to each other in a direction parallel to an upper surface of the first substrate 101.

In FIG. 6, the first interconnection patterns 130 of the first layer L1 may be disposed in the first interlayer insulating layer 140 and may be formed of a conductive material, such as a metal, a metal compound, or the like. The first interconnection patterns 130 may include a first uppermost interconnection 135 positioned on an uppermost end in the first direction. The first uppermost interconnection 135 may be an interconnection positioned furthest from the first substrate 101 in the first direction, and may be an interconnection positioned closest to the second layer L2 among the first interconnection patterns 130. The first uppermost interconnection 135 may be disposed in the first bonding insulating layer 145A positioned on an uppermost end in the first direction, and may be bonded to the second uppermost interconnection 235 included in the second layer L2. The second uppermost interconnection 235 bonded to the first uppermost interconnection 135 may be defined as the second uppermost upper interconnection.

The first bonding insulating layer 145A may be bonded to the second upper bonding insulating layer 245 of the second layer L2, and each of the first bonding insulating layer 145A and the second upper bonding insulating layer 245 may include silicon oxide and silicon carbon nitride. The first layer L1 and the second layer L2 may be understood to be bonded to each other by hybrid bonding. Accordingly, differently from the semiconductor device 100 described with reference to FIG. 4, in the semiconductor device 100A according to the embodiment illustrated in FIG. 6, the second layer L2 may be disposed such that the first surface 2FS of the second substrate 201 of the second layer L2 may face the first layer L1.

The first surface 2FS of the second substrate 201 may be a surface on which a plurality of fin structures 204 providing a channel region, a plurality of gate structures 205, and an element separator 203 may be formed. A source region and a drain region providing a plurality of elements may be formed on both sides of the plurality of fin structures 204 together with a plurality of gate structures 205. A plurality of elements formed on the second layer L2 may provide a core region, and in one or more embodiments, the plurality of elements may be implemented as a structure other than a FinFET, such as a horizontal transistor, a vertical transistor, or an MBCFET.

In FIG. 6, second upper interconnection patterns 230 and a second upper interlayer insulating layer 240 may be formed on the first surface 2FS of the second substrate 201, and second lower interconnection patterns 237 and a second lower bonding insulating layer 220 may also be formed on the second surface 2SS of the second substrate 201. Among the second lower interconnection patterns 237, interconnections positioned farthest from the second surface 2SS of the second substrate 201 in the first direction may be defined as a second uppermost lower interconnection 239. The second uppermost lower interconnection 239 may be positioned at the same level as the second lower bonding insulating layer 225, and may be bonded to the third uppermost upper interconnection 335 of the third layer L3 on the second boundary BDL2. The second uppermost lower interconnection 239 may be positioned farthest from the second surface 2SS of the second substrate 201 in the first direction among the second lower interconnection patterns 237, and may be positioned closest to the third layer L3 among the second lower interconnection patterns 237.

In the second boundary BDL2, the second lower bonding insulating layer 225 of the second layer L2 and the third upper bonding insulating layer 345 of the third layer L3 may be bonded to each other. Each of the second lower bonding insulating layer 225 and the third upper bonding insulating layer 345 may be formed of silicon oxide, silicon carbonitride, or the like. Accordingly, in the example embodiment illustrated in FIG. 6, the bonding structures of the first boundary BDL1 and the second boundary BDL2 may be the same, and for example, the first layer L1 and the second layer L2, and the second layer L2 and the third layer L3 may be bonded to each other as a hybrid bonding structure.

The third layer L3 may provide a peripheral circuit region in which an input/output interface, a logic circuit, or the like, are disposed. For example, the third layer L3 may include a third substrate 301, a plurality of elements providing a peripheral circuit region, a third upper interconnection patterns 330, and a third upper interlayer insulating layer 340. The structure and the stacking direction of the third layer L3 may be similar to the example embodiment described above with reference to FIG. 4.

In FIG. 6, a pair of bonding insulating layers 145A and 220 in the first boundary BDL1 may be coupled to each other, and a pair of bonding insulating layers 225 and 345 in the second boundary BDL2 may be coupled to each other. Also, the first boundary BDL1 may have a bonding structure in which uppermost interconnections 135 and 235 opposing each other are coupled to each other, and the second boundary BDL2 may also have a bonding structure in which uppermost interconnections 239 and 335 opposing each other are coupled to each other. The third uppermost upper interconnection 335 may be defined as an interconnection positioned closest to the second layer L2 among the third upper interconnection patterns 330.

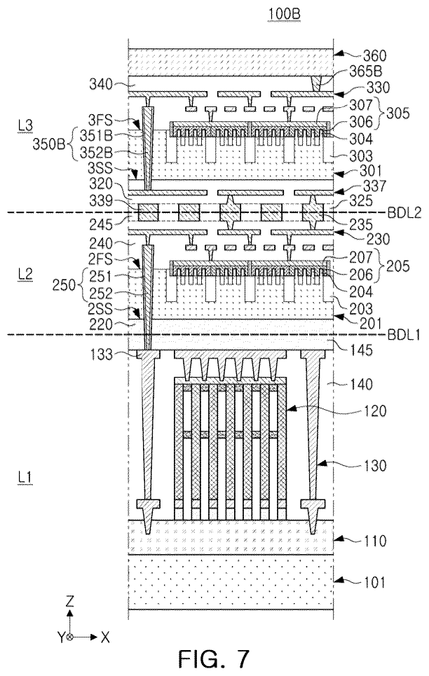

Referring to FIG. 7, a semiconductor device 100B according to one or more embodiments may include a plurality of layers stacked in the first direction, a first boundary BDL1 may be defined between the first layer L1 and the second layer L2, and a second boundary BDL2 may be defined between the second layer L2 and the third layer L3. The first layer L1 may provide a cell region in which a plurality of memory cells are disposed, the second layer L2 may provide a core region in which a row decoder, a sense amplifier circuit, a column decoder, or the like, are disposed, and the third layer L3 may provide a peripheral circuit region in which an input/output interface, a logic circuit, or the like, are disposed.

In FIG. 7, the structure and the stacking direction of the first layer L1 and the second layer L2 may be similar to that described above with reference to FIG. 4. Referring to FIG. 7, the first layer L1 may include a first substrate 101, a first element region 110, capacitor structures 120, first interconnection patterns 130, and a first interlayer insulating layer 140. A first bonding insulating layer 145 positioned farthest from a first surface of the first substrate 101 in the first direction may be bonded to a second lower bonding insulating layer 220 disposed on a second surface 2SS of the second substrate 201 on the second layer L2. The first layer L1 and the second layer L2 may be electrically connected to each other through a second via structure 250.

In FIG. 7, the third layer L3 may be stacked on the second layer L2 such that the second surface 3SS of the third substrate 301 may be positioned closer to the second layer L2 than the first surface. In the third layer L3, a third lower interlayer insulating layer 320, third lower interconnection patterns 337, or the like, are disposed on the second surface 3SS of the third substrate 301, and a third uppermost lower interconnection 339 and a third lower bonding insulating layer 325 positioned farthest from the second surface in the first direction may be defined. In the second boundary BDL2, the third uppermost lower interconnection 339 may be bonded to the second uppermost upper interconnection 235 of the second layer L2, and the third lower bonding insulating layer 325 may be bonded to the second upper bonding insulating layer 245. Accordingly, in the semiconductor device 100B in FIG. 7, the bonding structure in the first boundary BDL1 and the bonding structure in the second boundary BDL2 may be different from each other.

A plurality of fin structures 304, a plurality of gate structures 305, and an element separator 303, which provide a channel region, may be formed on the first surface 3FS of the third substrate 301. Third upper interconnection patterns 330 and a third upper interlayer insulating layer 340 may be disposed on the first surface, and at least one of the third upper interconnection patterns 330 may be connected to the pad 360 through a pad via 365B. At least a portion of the third upper interconnection patterns 330 may be connected to the third lower interconnection patterns 337 through a third via structure 350B. Accordingly, a peripheral circuit region of a third layer L3 may be electrically connected to a core region of a second layer L2 through the third via structure 350B.

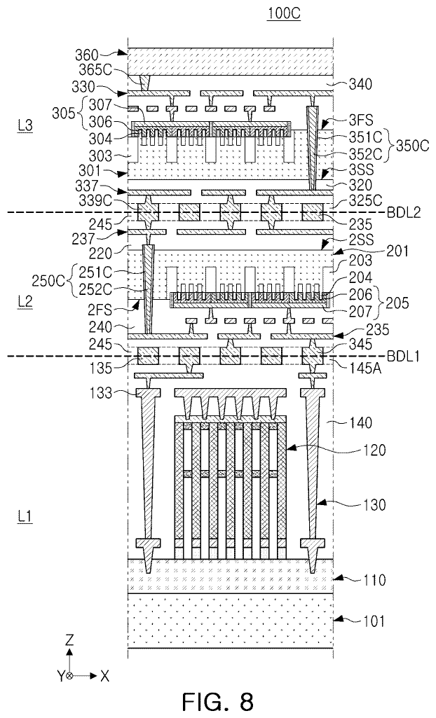

Referring to FIG. 8, a semiconductor device 100C according to one or more embodiments may include a plurality of layers stacked in the first direction, a first boundary BDL1 may be defined between the first layer L1 and the second layer L2, and a second boundary BDL2 may be defined between the second layer L2 and the third layer L3. The first layer L1 may provide a cell region in which a plurality of memory cells are disposed, the second layer L2 may provide a core region in which a row decoder, a sense amplifier circuit, a column decoder, or the like, are disposed, and the third layer L3 may provide a peripheral circuit region in which an input/output interface, a logic circuit, or the like, are disposed.

In FIG. 8, the structure and the stacking direction of the first layer L1 and the second layer L2 may be similar to that described above with reference to FIG. 6. Referring to FIG. 8, the first bonding insulating layer 145 positioned farthest from the first surface of the first substrate 101 in the first direction may be bonded to the second upper bonding insulating layer 245 disposed on the first surface 2FS of the second substrate 201 on the second layer L2. Also, the first uppermost interconnection 135 of the first layer L1 may be bonded to the second uppermost upper interconnection 235 of the second layer L2. Accordingly, in the first boundary BDL1, the first layer L1 and the second layer L2 may be bonded to each other with a bonding structure according to a hybrid bonding process.

The bonding structure of the second layer L2 and the third layer L3 may be similar to the bonding structure of the first layer L1 and the second layer L2. Referring to FIG. 8, among the second lower interconnection patterns 237 disposed on the second surface 2SS of the second substrate 201 on the second layer L2, the second uppermost lower interconnection 239 may be bonded to the third uppermost upper interconnection 335 among the third upper interconnection patterns 330 of the third layer L3. Also, the second lower bonding insulating layer 225 of the second layer L2 may be bonded to the third upper bonding insulating layer 345 of the third layer L3.

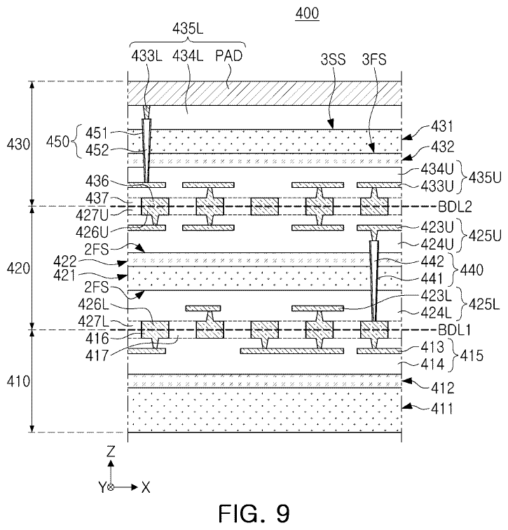

FIGS. 9, 10, 11 and 12 are diagrams illustrating a bonding structure of layers included in a semiconductor device according to one or more embodiments.

Referring to FIGS. 9 to 12, a semiconductor device 400 according to one or more embodiments may include first to third layers 410, 420, and 430 stacked in the first direction (Z-axis direction). The first layer 410 may provide a cell region, the second layer 420 may provide a core region, and the third layer 430 may provide a peripheral circuit region.

In one or more embodiments, a plurality of memory cells operating as a dynamic random access memory (DRAM) may be disposed on the first layer 410, a row decoder, a sense amplifier circuit, a column decoder, or the like, may be disposed on the second layer 420, and an input/output interface, a logic circuit, or the like, may be disposed in the third layer 430. Also, in one or more embodiments, a computation circuit for performing computation in the semiconductor device 400 may be disposed in at least one of the second layer 420 and the third layer 430. The computation circuit may perform a mandatory access control (MAC) computation, or the like, for implementing an arterial intelligence (AI) function in a system including a semiconductor device 400, and may perform, for example, a computation using input data received from an external entity through an input/output interface, and read data read from a cell region.

First, referring to FIG. 9, the first layer 410 may include a first substrate 411, a first element region 412, and a first interconnection region 415. The first element region 412 and the first interconnection region 415 may be defined in order on the first surface of the first substrate 411, and the first interconnection region 415 may include first interconnection patterns 413 and a first interlayer insulating layer 414. Elements for implementing memory cells of DRAM, such as a cell transistor, may be disposed in the first element region 412, and capacitor structures may be disposed in the first interconnection region 415.

The first interconnection region 415 may include a first uppermost interconnection 416 positioned on the uppermost layer in the first direction, and a first bonding insulating layer 417. The first uppermost interconnection 416 may be positioned farthest from the first substrate 411 in the first direction in the first interconnection region 415. The first uppermost interconnection 416 and the first bonding insulating layer 417 may be coupled to the second layer L2 in a hybrid bonding method on the first boundary BDL1. For example, as illustrated in FIG. 9, the first uppermost interconnection 416 may be bonded to the second uppermost lower interconnection 426L of the second layer L2, and the first bonding insulating layer 417 may be bonded to the second lower bonding insulating layer 427L of the second layer L2. The first boundary BDL1 may have a first bonding structure in which a pair of bonding insulating layers 417 and 427L are bonded to each other, and uppermost interconnections 416 and 426L opposing each other are bonded to each other. The second uppermost lower interconnection 426L may be positioned farthest from the second substrate 421 in the first direction in the second lower interconnection region 425L.

The second layer L2 may include the second substrate 421, a second element region 422, a second upper interconnection region 425U, and a second lower interconnection region 425L. The second upper interconnection region 425U may include a second upper interconnection patterns 423U and a second upper interlayer insulating layer 424U, and the second lower interconnection region 425L may include a second lower interconnection patterns 423L and a second lower interlayer insulating layer 424L.

In FIGS. 9 to 12, the second layer L2 may have a structure in which a first surface 2FS of the second substrate 421, on which the second element region 422 is formed, faces the third layer L3 in the first direction. In FIG. 9, the second uppermost upper interconnection 426U and the second upper bonding insulating layer 427U included in the second upper interconnection region 425U may be coupled to the third layer L3 in a hybrid bonding method on the second boundary BDL2. The second uppermost upper interconnection 426U may be coupled to the third uppermost upper interconnection 436 of the third layer L3, and the second upper bonding insulating layer 427U may be coupled to the third upper bonding insulating layer 437 of the third layer L3. Accordingly, the second boundary BDL2 may also have a first bonding structure similarly to the first boundary BDL1. The second uppermost upper interconnection 426U may be positioned furthest from the first surface 2FS of the second substrate 421 in the first direction in the second upper interconnection region 425U. The third uppermost upper interconnection 436 may be positioned furthest from the first surface 3FS of the third substrate 431 in the first direction in the third upper interconnection region 435U.

A second via structure 440 penetrating the second substrate 421 may be formed on the second layer L2. The second via structure 440 may include a via insulating layer 441 and a via conductive layer 442, and may electrically connect a portion of the second upper interconnection patterns 423U to a portion of the second lower interconnection patterns 423L.

In FIGS. 9 to 12, the third layer L3 may have a structure in which a first surface 3FS of the third substrate 431, on which a third element region 432 is formed, faces the second layer L2 in the first direction. A third lower interconnection region 435L may be formed on the second surface 3SS of the third substrate 431, and the third lower interconnection region 435L may include a pad via 433L and a third lower interlayer insulating layer 434L, and a pad PAD may be disposed on the third lower interlayer insulating layer 434L. The pad PAD may be connected to the third via structure 450 through the pad via 433L. The third via structure 450 may include a via insulating layer 451 and a via conductive layer 452, and may penetrate the third substrate 431 and may be connected to a portion of the third upper interconnection patterns 433U.

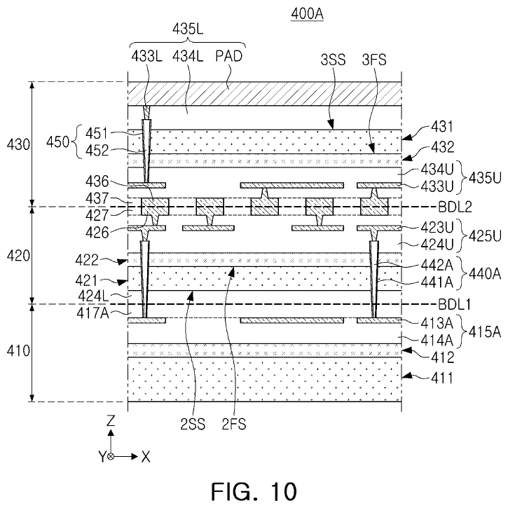

Thereafter, in the semiconductor device 400A in FIG. 10, the bonding structure of the first boundary BDL1 may be different from the bonding structure of the second boundary BDL2. Referring to FIG. 10, the bonding structure of the second boundary BDL2 may be similar to that described with reference to FIG. 9, and may be the first bonding structure. The bonding structure of the first boundary BDL1 may be different from the first bonding structure.

In FIG. 10, the first layer L1 and the second layer L2 may be coupled to each other by coupling between the first bonding insulating layer 417A of the first layer L1 and the second lower interlayer insulating layer 424L of the second layer L2. At least a portion of the first interconnection patterns 413A included in the first interconnection region 415A of the first layer L1 may be connected to second via structures 440A penetrating the second substrate 421. Accordingly, the first boundary BDL1 may have a second bonding structure in which the pair of bonding insulating layers 417A and 424L are coupled to each other and at least one second via structure 440A penetrates the pair of bonding insulating layers 417A and 424L.

The second via structures 440A may extend to a length penetrating the second substrate 421 and the second lower interlayer insulating layer 424L and may contact at least a portion of the first interconnection patterns 413A. The second via structures 440A may be connected to a portion of the second upper interconnection patterns 423U on the first surface 2FS of the second substrate 421.

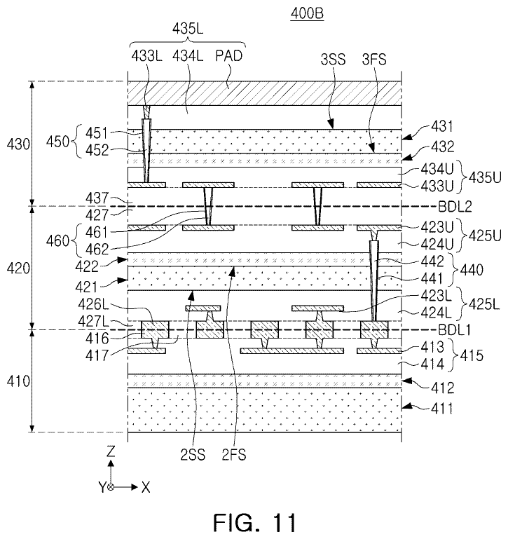

Referring to FIG. 11, the bonding structure of the first boundary BDL1 of the semiconductor device 400B may be different from the bonding structure of the second boundary BDL2. In FIG. 11, the bonding structure of the first boundary BDL1 may be the first bonding structure described with reference to FIG. 9. For example, as illustrated in FIG. 11, the first uppermost interconnection 416 and the second uppermost lower interconnection 426L may be bonded to each other, and the first bonding insulating layer 417 may be bonded to the second lower bonding insulating layer 427L, such that the first layer L1 and the second layer L2 may be coupled to each other.

In FIG. 11, the second layer L2 and the third layer L3 may be bonded to each other by coupling between the second upper bonding insulating layer 427B of the second layer L2 and the third upper bonding insulating layer 437B of the third layer L3. At least a portion of second upper interconnection patterns 423U included in second upper interconnection region 425U of the second layer L2 may be connected to at least a portion of third upper interconnection patterns 433U included in third upper interconnection region 435U of the third layer L3 through a third connection via structure 460. Accordingly, second boundary BDL2 may have a second bonding structure in which a pair of bonding insulating layers 427B and 437B are coupled to each other, and at least one third connection via structure 460 penetrates the pair of bonding insulating layers 427B and 437B.

The third connection via structure 460 may penetrate the second upper bonding insulating layer 427B and the third lower bonding insulating layer 437B, and may include a first conductive layer 461 and a second conductive layer 462. However, the structure of the third connection via structure 460 may vary in one or more embodiments. At least one of the third upper interconnection patterns 433U may be electrically connected to a third lower interconnection region 435L of the third layer L3 and a pad PAD through a third via structure 450 penetrating the third substrate 431.

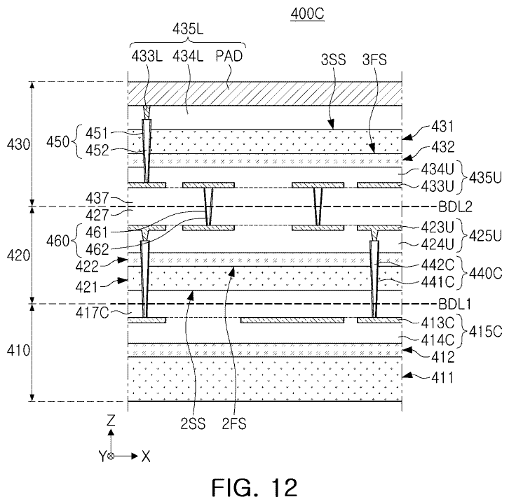

Referring to FIG. 12, the bonding structure of the second boundary BDL2 of the semiconductor device 400C may be the second bonding structure described above with reference to FIG. 11. For example, as illustrated in FIG. 12, the second upper bonding insulating layer 427C and the third upper bonding insulating layer 437C may be coupled to each other, such that the second layer L2 and the third layer L3 may be stacked. Third via structures 460 penetrating the second upper bonding insulating layer 427C and the third upper bonding insulating layer 437C may be disposed on the second boundary BDL2.

In FIG. 12, the bonding structure of the first boundary BDL1 may be the second bonding structure as that of the second boundary BDL2. Referring to FIG. 12, in the first boundary BDL1, the first bonding insulating layer 417C of the first layer L1 may be bonded to the second lower interlayer insulating layer 424L of the second layer L2. At least a portion of the first interconnection patterns 413C of the first layer L1 may be electrically connected to at least a portion of the second upper interconnection patterns 423U of the second layer L2 through second via structures 440C penetrating the second substrate 421.

As described with reference to FIGS. 9 to 12, in one or more embodiments, the bonding structure on the first boundary BDL1 and the second boundary BDL2 may be determined in various combinations. Also, the bonding structure in the first boundary BDL1 and the second boundary BDL2 according to the example embodiments described with reference to FIGS. 9 to 12 may also be applied to the structure in which the stacking direction of the second layer L2 and/or the third layer L3 is modified.

For example, the bonding structure on the first boundary BDL1 and the second boundary BDL2 according to the embodiments described with reference to FIGS. 9 to 12 may be applied to a structure in which the second layer L2 may be stacked such that the second element region 422 and the second upper interconnection region 425U may face the first layer L1. Also, in one or more embodiments, the bonding structure on the first boundary BDL1 and the second boundary BDL2 according to the embodiments described with reference to FIGS. 9 to 12 may be applied to a structure in which the second layer L2 may be stacked such that the third element region 432 and the third upper interconnection region 435U may face the pad PAD rather than the second layer L2.

In the embodiments described with reference to FIGS. 9 to 12, a computation circuit for implementing functions such as PIM and IMC may be disposed on the second layer L2 and/or the third layer L3. The computation circuit may execute MAC computation, or the like, and may execute a computation using input data received through the pad PAD by the input/output interface of the third layer L3, and/or read data read by a sense amplifier circuit from the cell region of the first layer L1.

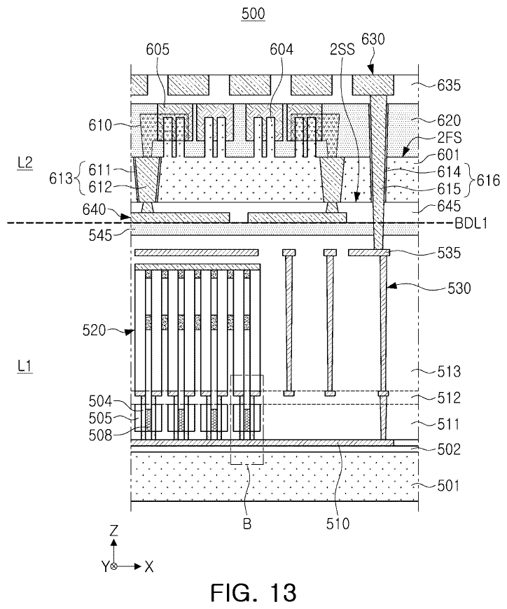

FIGS. 13, 14, 15 and 16 are diagrams illustrating a structure of a semiconductor device according to one or more embodiments.

FIGS. 13 to 16 may be diagrams illustrating a method of forming power interconnection in a second layer L2 on which a core region is formed in semiconductor devices 500, 500A, and 500B according to one or more embodiments. In the embodiments described with reference to FIGS. 13 to 16, the third layer may not be provided, but a third layer may be stacked on the second layer L2 in the semiconductor devices 500, 500A, and 500B.

Referring to FIG. 13, the semiconductor device 500 according to one or more embodiments may have a structure in which a first layer L1 and a second layer L2 are stacked in the first direction (Z-axis direction). A cell region including a plurality of memory cells may be formed on the first layer L1, and a core region including a row decoder, a sense amplifier circuit, and a column decoder may be formed on the second layer L2. As described above, a third layer may be stacked on the second layer L2, and an input/output interface, a logic circuit, or the like, may be disposed in the third layer.

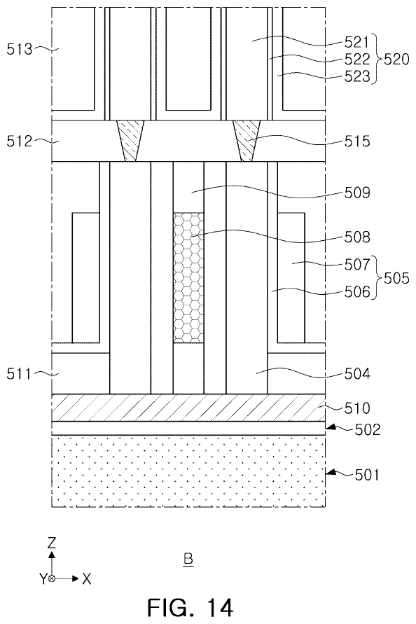

Each of the memory cells included in the first layer L1 may include a cell transistor and a capacitor structure 520. In FIG. 13, the cell transistor may be implemented as a vertical channel transistor. For example, the first layer L1 may include a first substrate 501, a substrate insulating layer 502, a bitline structure 510, a vertical channel layer 504, a gate structure 505, a back gate structure 508, first interlayer insulating layers 511-513, and first interconnection patterns 530. Hereinafter, the structure of the cell transistor included in the memory cell will be described in greater detail with reference to FIG. 14, an enlarged diagram illustrating region “B.”

As illustrated in FIG. 14, a substrate insulating layer 502 may be disposed on a first substrate 501, and a bitline structure 510 may be formed thereon using a conductive material. The bitline structure 510 may extend in the second direction (X-axis direction) and may be connected to a vertical channel layer 504 in the first direction. The vertical channel layer 504 may include a semiconductor material, and a gate structure 505 and a back gate structure 508 may be disposed on both sides of the vertical channel layer 504 in the second direction. The gate structure 505 may include a gate insulating layer 506 and a gate electrode layer 507, and the gate electrode layer 507 may extend in the third direction (Y-axis direction) and may provide a wordline structure. An insulating layer 509 may be disposed above and below the back gate structure 508 in the first direction.

The vertical channel layer 504 may be connected to the bitline structure 510 on one side in the first direction and may be connected to the lower contact structure 515 on the other side. The lower contact structure 515 may be connected to the capacitor structure 520, and the capacitor structure 520 may include a lower electrode layer 521, a capacitor dielectric layer 522, and an upper electrode layer 523. As described above with reference to FIG. 5, the capacitor structure 520 may be implemented in a shape different from the pillar shape illustrated in FIG. 14.

However, the structure of the cell transistors and the capacitor structures 520 is not necessarily limited to the example illustrated in FIG. 14. For example, the cell transistors may be implemented in a structure different from the vertical channel transistor example illustrated in FIG. 14, for example, a structure of a buried transistor. Also, the cell region may be implemented in a three dimensional structure in which the cell transistors and capacitor structures 520 may be connected in a direction parallel to the first surface of the first substrate 501, rather than in the first direction.

Referring back to FIG. 13, the first layer L1 and the second layer L2 may be stacked by bonding between the first bonding insulating layer 545 and the second lower bonding insulating layer 645 on the first boundary BDL1. On the second layer L2, elements for providing a core region may be formed on the first surface 2FS of the second substrate 601, and the second lower bonding insulating layer 645 may be formed on the second surface.

A plurality of fin structures 604 providing a channel region of the elements may be formed on the first surface 2FS of the second substrate 601, and a plurality of gate structures 605 may be formed in a shape passing over the plurality of fin structures 604. A plurality of active regions 610 providing a source region or a drain region may be connected to the plurality of fin structures 604. For example, the plurality of active regions 610 may be connected to both sides of the plurality of fin structures 604 in the third direction. The plurality of gate structures 605 and the plurality of active regions 610, or the like, may be disposed in a second upper interlayer insulating layer 620 formed on the first surface of a second substrate 601.

On the second layer L2, a plurality of second upper interconnection patterns 630 may be disposed in a second upper interlayer insulating layer 635 on a first surface 2FS of the second substrate 601. The plurality of second upper interconnection patterns 630 may provide a path for transferring a signal and may be connected to a cell region of the first layer L1 through the second via structure 616. For example, referring to FIG. 13, the second via structure 616 may extend to a landing pad 535 of the first layer L1, and the bitline structure 510 may be electrically connected to the second layer L2 through the second via structure 616. The second via structure 616 may provide an electrical connection between the bitline structure 510 and a sense amplifier circuit. The second via structure 616 may include a via insulating layer 614 and a via conductive layer 615.

At least a portion of the plurality of active regions 610 may be connected to a power interconnection 640 positioned in a second lower bonding insulating layer 645 through a power via 613. The power via 613 may include a via insulating layer 611 and a via conductive layer 612. The power interconnection 640 and the power via 613 may provide a transfer path of power voltage required for operation of the core region implemented on the second layer L2.

In FIG. 13, the process of forming the power interconnection 640 may be as below. First, a plurality of elements may be formed on a first surface 2FS of the second substrate 601, and by performing an etching process from the first surface 2FS of the second substrate 601, the power via 613 may be formed. Thereafter, the power via 613 may be exposed by performing a polishing process on the second surface 2SS of the second substrate 601, and a power interconnection 640 and a second lower bonding insulating layer 645, or the like, may be formed on the second surface 2SS of the second substrate 601. The process of forming a plurality of second upper interconnection patterns 630 electrically connected to a plurality of elements may be performed before the formation of the power interconnection 640 or after the formation of the power interconnection 640.

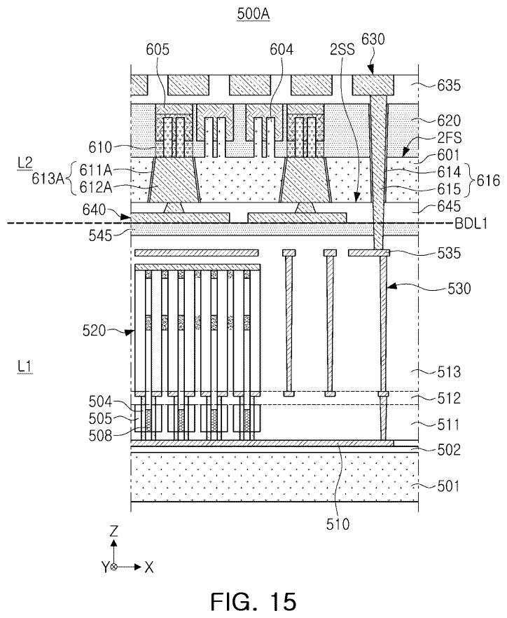

Referring to FIG. 15, a semiconductor device 500A according to one or more embodiments may have a structure in which a first layer L1 and a second layer L2 are stacked in the first direction (Z-axis direction). The structure of the first layer L1 may be understood with reference to the example embodiment described with reference to FIGS. 13 and 14 above.

In FIG. 15, the power via 613A may have a structure different from FIG. 13. This may be because the order of performing processes for forming the power via 613A and the power interconnection 640A may be different from the example described with reference to FIG. 13.

For example, in FIG. 15, a plurality of elements may be formed on a first surface of a second substrate 601, and second upper interconnection patterns 630 connected to the plurality of elements may be formed. Thereafter, by performing an etching process from the second surface 2SS of the second substrate 601, the power via 613A connected to at least a portion of the plurality of active regions 610A may be formed. When the power via 613A is formed, a second lower bonding insulating layer 645 and a power interconnection 640 may be formed on the second surface 2SS of the second substrate 601. In one or more embodiments, prior to performing an etching process from the second surface 2SS of the second substrate 601 to form the power via 613A, a thickness of the second substrate 601 may be reduced by performing a polishing process.

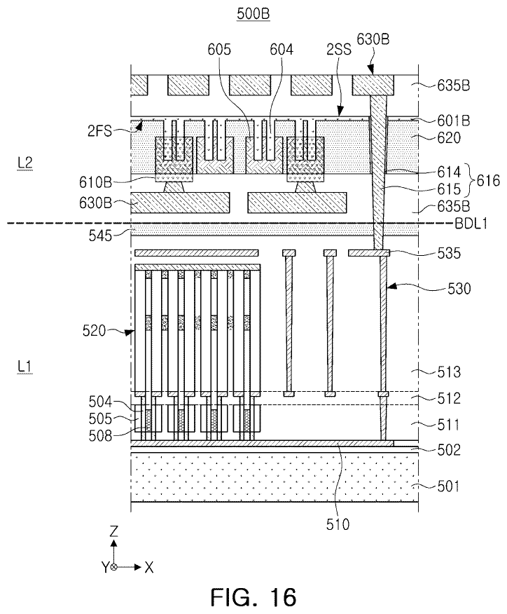

Thereafter, referring to FIG. 16, a semiconductor device 500B according to one or more embodiments may have a structure in which a first layer L1 and a second layer L2 are stacked in the first direction (Z-axis direction). The structure of the first layer L1 may be understood with reference to the example embodiment described with reference to FIGS. 13 and 14 above.

In FIG. 16, a plurality of active regions 610B may be connected to a power interconnection 630B without a power via penetrating the second substrate 601B. In FIG. 16, a power interconnection 640B may be disposed on a first surface on which a plurality of fin structures 604, a plurality of gate structures 605 and a plurality of active regions 610B may be formed in the second substrate 601B. This may be because the order of performing the process of forming the power interconnection 640B may be different from the example described with reference to FIG. 13 above.

For example, in FIG. 16, a plurality of elements may be formed on a first surface 2FS of the second substrate 601B, and the power interconnection 640B connected to at least a portion of the plurality of active regions 610B may be formed. The power interconnection 640B may be disposed in a second upper interlayer insulating layer 635B formed on the first surface 2FS of the second substrate 601B.

When the power interconnection 640B is formed, a thickness of the second substrate 601B may be reduced by performing a polishing process on the second surface 2SS of the second substrate 601B, and a second upper interconnection patterns 630 may be formed on the second surface 2SS of the second substrate 601B. The second upper interconnection patterns 630 may be connected to the second via structure 616 connecting a plurality of elements of the second layer L2 to memory cells of the first layer L1. Accordingly, differently from the example embodiments in FIGS. 13 and 15, in which the interconnection patterns providing a transfer path of a signal are disposed on the first surface 2FS of the second substrate 601, and the power interconnection 640 and 640A providing a transfer path of a power voltage are disposed on the second surface 2SS of the second substrate 601, in FIG. 16, the interconnection patterns providing a transfer path of a signal may be disposed on a second surface 2SS of the second substrate 601B, and the power interconnection 640B providing a transfer path of a power voltage may be disposed on the first surface 2FS of the second substrate 601B.

In the embodiments described with reference to FIGS. 13 to 16, a computation circuit for implementing functions such as PIM and IMC may be disposed on the second layer L2. The computation circuit may execute a MAC computation, or the like, and may execute a computation using read data read by a sense amplifier circuit from the cell region of the first layer L1, and/or input data received from another external device through the input/output interface.

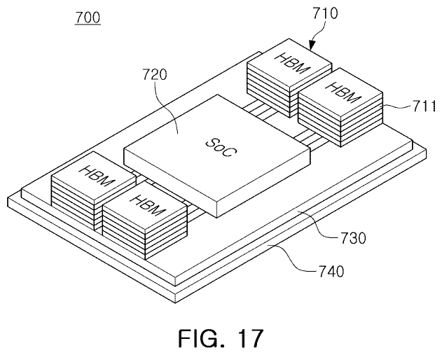

FIG. 17 is a diagram illustrating a system including a semiconductor device according to one or more embodiments.

Referring to FIG. 17, a system 700 may include a plurality of semiconductor packages 710 and a system-on-chip (SOC) 720. Each of the plurality of semiconductor packages 710 may have a structure in which a plurality of semiconductor devices 711 are stacked, and may be, for example, a high bandwidth memory (HBM). The plurality of semiconductor packages 710 and the system-on-chip may be electrically connected to each other through an interposer substrate 730, and the interposer substrate 730 may be stacked on a package substrate 740.

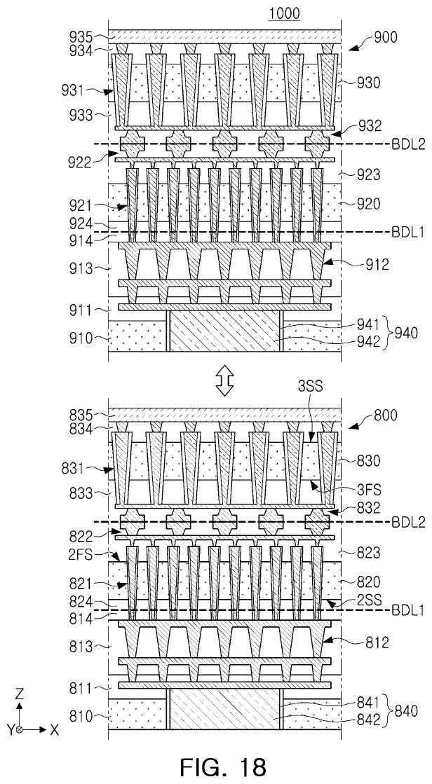

In FIG. 17, each of a plurality of semiconductor devices 711 included in a semiconductor package 710 may have a structure in which a plurality of semiconductor dies are stacked as in the embodiments described above. Also, the plurality of semiconductor devices 711 included in a semiconductor package 710 may be electrically connected to each other through a through silicon via (TSV). However, when two or more semiconductor devices 711 in which a plurality of semiconductor dies are already stacked are stacked and a through silicon via penetrating the same is formed, the issues such as cracks may occur. Hereinafter, examples of a structure in which two or more semiconductor devices 711 are stacked and electrically connected to each other according to one or more embodiments will be described with reference to FIGS. 18 to 21.

FIGS. 18, 19, 20 and 21 are diagrams illustrating a stack structure of semiconductor devices according to one or more embodiments.

In FIGS. 18 to 21, each of semiconductor packages 1000, 1000A, 1000B, and 1000C may include first semiconductor devices 800, 800A, 800B, and 800C and second semiconductor devices 900, 900A, 900B, and 900C stacked in the first direction (Z-axis direction). Each of the first semiconductor devices 800, 800A, 800B, and 800C and the second semiconductor devices 900, 900A, 900B, and 900C may include a plurality of layers L1-L3 stacked in the first direction.

Referring to FIG. 18, in each of the first semiconductor device 800 and the second semiconductor device 900, the first layer L1 may provide a cell region, the second layer L2 may provide a core region, and the third layer L3 may provide a peripheral circuit region. The first semiconductor device 800 and the second semiconductor device 900 have the same structure, and accordingly, the structure of the second semiconductor device 900 may also be understood by referring to the description of the structure of the first semiconductor device 800. In each of the first semiconductor device 800 and the second semiconductor device 900, a computation circuit for implementing PIM, IMC, or the like, may be disposed on at least one of the second layer L2 and the third layer L3.

Referring to the first semiconductor device 800, the first layer L1 may include a first substrate 810 and a first element region 811, and first interconnection patterns 812 and a first interlayer insulating layer 813 may be disposed on the first element region 811. The first layer L1 may include a through silicon via 840 penetrating the first substrate 810, and the through silicon via 840 may include an insulating layer 841 and a conductive layer 842.

The through silicon via 840 may have a relatively large diameter as compared to each of the other via structures 821 and 831, and may thus have an excellent signal transfer characteristic. However, when the through silicon via 840 penetrating the first to third layers L1-L3 is formed by a single etching process, cracks may occur in the semiconductor device 800, and reliability may be lowered.

Accordingly, in FIG. 18, the through silicon via 840 may be formed only on the first layer L1. The first interconnection patterns 812 connected to the through silicon via 840 may have a structure in which a plurality of line patterns are connected to each other, for example, a mesh structure, so as to reduce a RC delay of a signal transferred to the through silicon via 840.

The first bonding insulating layer 814 and the second lower bonding insulating layer 824 may be bonded to each other on the first boundary BD1 between the first layer L1 and the second layer L2, such that the first layer L1 and the second layer L2 may be coupled to each other. Each of the first bonding insulating layer 814 and the second lower bonding insulating layer 824 may be formed of silicon oxide, silicon carbon nitride, or the like. The first interconnection patterns 812 may be electrically connected to the second upper interconnection patterns 822 disposed on the first surface 2FS of the second substrate 820 through second via structures 821 penetrating the second substrate 820, the second lower bonding insulating layer 824, and the first bonding insulating layer 814. The second upper interconnection patterns 822 may be disposed on the second upper interlayer insulating layer 823 formed on the first surface 2FS of the second substrate 820. The second layer L2 may be disposed such that the first surface on which elements may be formed in the second substrate 820 may face the third layer L3 in the first direction, and the second surface 2SS of the second substrate 820, opposing the first surface, may face the first layer L1 in the first direction.

In the second boundary BDL2, a second uppermost interconnection among the second upper interconnection patterns 822 of the second layer L2 and a third uppermost interconnection among the third upper interconnection patterns 832 of the third layer L3 may be bonded to each other. Also, the insulating layer disposed on the uppermost layer of the second upper interlayer insulating layer 823 of the second layer L2 may be bonded to the insulating layer disposed on the uppermost layer of the third upper interlayer insulating layer 833 of the third layer L3. The second layer L2 and the third layer L3 may be coupled to each other by a hybrid bonding method in the second boundary BDL2 as described above.

As for the third layer L3, the first surface on which elements may be formed in the third substrate 830 may face the second layer L2 in the first direction. The third upper interconnection patterns 832 may be electrically connected to the pad 835 disposed on the second surface 3SS of the third substrate 830 through a plurality of third via structures 831 penetrating the third substrate 830. The pad 835 may be disposed on the third lower interlayer insulating layer 834 formed on the second surface 3SS of the third substrate 830 and may be exposed.

In FIG. 18, the second upper interconnection patterns 822 and the third upper interconnection patterns 832 may also have a structure in which a plurality of line patterns are interconnected to reduce a RC delay of a signal transferred through the silicon via 840. Also, as illustrated in the example in FIG. 18, a plurality of second via structures 821 and a plurality of third via structures 831 may be connected to a through silicon via 840.

The second semiconductor device 900 stacked with the first semiconductor device 800 may have the same structure as that of the first semiconductor device 800. Accordingly, in the semiconductor package 1000 in which the first semiconductor device 800 and the second semiconductor device 900 are stacked, the through silicon via 940 included in the second semiconductor device 900 may be connected to the pad 835 of the first semiconductor device 800. In FIG. 18, the through silicon vias 840 and 940 may be disposed only on the first layer L1 providing the cell region.

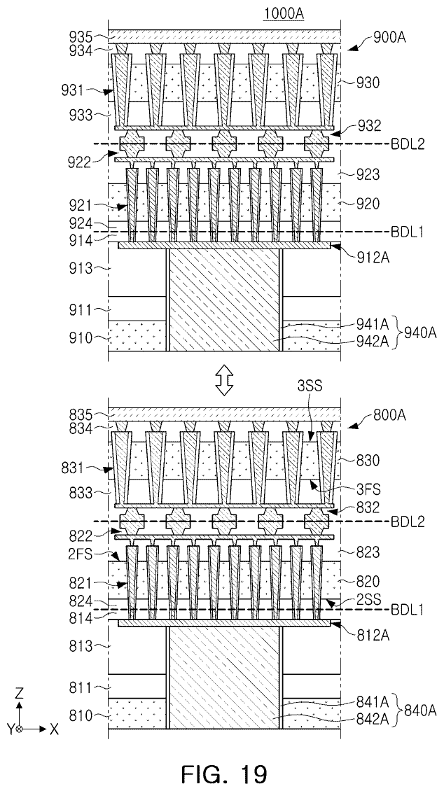

Referring to FIG. 19, in each of the first semiconductor device 800A and the second semiconductor device 900A included in the semiconductor package 1000A, the second layer L2 and the third layer L3 may have the same structure as that described with reference to FIG. 18 above. However, in FIG. 19, through silicon vias 840A and 940A may penetrate the first substrates 810 and 910 and may extend from the first layer L1 to the first uppermost interconnection 812A disposed on the uppermost layer.

A first bonding insulating layer 814 may be disposed on the first uppermost interconnection 812A, and the first bonding insulating layer 814 may be bonded to the second lower bonding insulating layer 824 of the second layer L2. The first uppermost interconnection 812A may be connected to a plurality of second via structures 821 penetrating the second substrate 820.

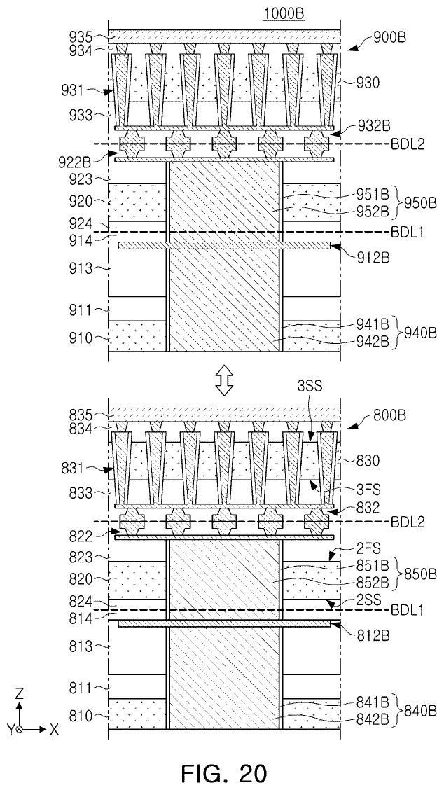

Thereafter, referring to FIG. 20, in each of the first semiconductor device 800B and the second semiconductor device 900B included in the semiconductor package 1000B, the third layer L3 may have the same structure as that of the third layer L3 described above with reference to FIG. 18. However, FIG. 20, the first semiconductor device 800B may include a first through silicon via 840B penetrating the first substrate 810 on the first layer L1 and a second through silicon via 850B penetrating the second substrate 820 on the second layer L2. Similarly, the second semiconductor device 900B may also include a first through silicon via 940B and a second through silicon via 950B. The through silicon vias 840B, 850B, 940B, and 950B may include insulating layers 841B, 851B, 941B, and 951B and conductive layers 842B, 852B, 942B, and 952B, respectively.

Referring to the first semiconductor device 800B, the first through silicon via 840B may extend to the first uppermost interconnection 812B of the first layer L1. On the first boundary BDL1, the first bonding insulating layer 814 of the first layer L1 and the second lower bonding insulating layer 824 of the second layer L2 may be bonded to each other, and the second through silicon via 850B may connect the second upper interconnection patterns 822 to the first uppermost interconnection 812B. Accordingly, the second through silicon via 850B may penetrate the second substrate 820, the first bonding insulating layer 814, and the second lower bonding insulating layer 824.

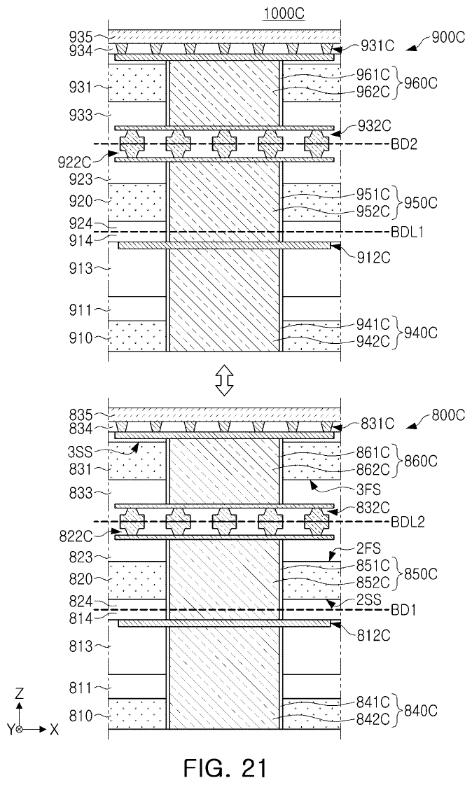

Referring to FIG. 21, in each of the first semiconductor device 800C and the second semiconductor device 900C included in the semiconductor package 1000C, the first layer L1 and the second layer L2 may have the same structure as that described with reference to FIG. 20 above. However, in FIG. 21, the third layer L3 may also include through silicon vias 860C and 960C. Accordingly, the first semiconductor device 800C may include a first through silicon via 840C disposed on the first layer L1, a second through silicon via 850C disposed on the second layer L2, and a third through silicon via 860C disposed on the third layer L3. Similarly, the second semiconductor device 900C may also include a first through silicon via 940C, a second through silicon via 950C and a third through silicon via 960C. Through silicon vias 840C, 850C, 860C, 940C, 950C, and 960C may include insulating layers 841C, 851C, 861C, 941C, 951C, and 961C and conductive layers 842C, 852C, 862C, 942C, 952C, and 962C, respectively.

Referring to the first semiconductor device 800C, in the second boundary BDL2, the second layer L2 and the third layer L3 may be coupled to in a hybrid bonding method. As illustrated in the example in FIG. 21, a second uppermost upper interconnection 822C and a third uppermost upper interconnection 832C may be bonded to each other, and an uppermost layer of the second upper interlayer insulating layer 823 and an uppermost layer of the third upper interlayer insulating layer 833 may also be bonded to each other. The third through silicon via 860C may penetrate the third substrate 831 and may connect a portion of the third upper interconnection patterns disposed on the first surface 3FS of the third substrate 831 to the third lower interconnection patterns 831C disposed on the second surface 3SS of the third substrate 831.

In each of the embodiments described with reference to FIGS. 18 to 21, the first semiconductor device 800, 800A, 800B, and 800C and the second semiconductor device 900, 900A, 900B, and 900C may have the same structure, but embodiments thereof is not limited thereto. For example, the first semiconductor device 800 illustrated in FIG. 18 and the second semiconductor device 900A illustrated in FIG. 19 may be stacked and may provide a single semiconductor package. The through silicon via described with reference to FIGS. 18 to 21 may also be applied to the semiconductor devices described with reference to FIGS. 4 to 16.

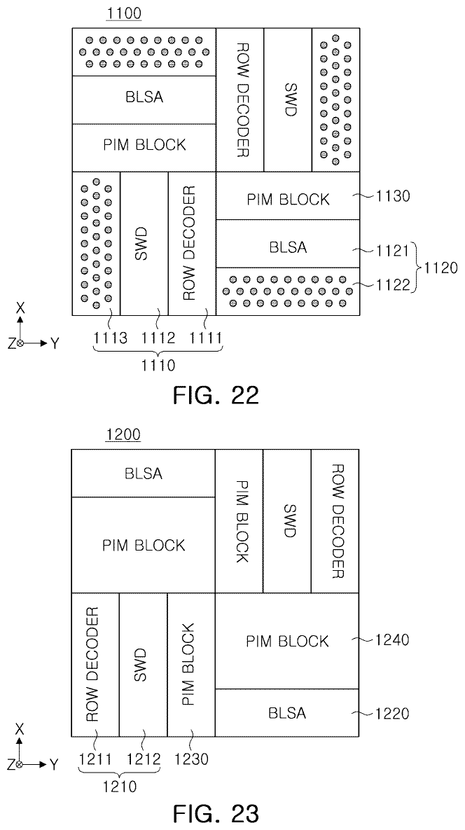

FIGS. 22 and 23 are diagrams illustrating a structure of a core region included in a semiconductor device according to one or more embodiments.

As described above, in one or more embodiments, in core regions 1100 and 1200 a row decoder, a bitline amplifier, or the like, which drives memory cells disposed in a cell region, may be disposed. The core regions 1100 and 1200 may be manufactured on wafers different from the cell region and may be stacked with the cell region, and the core regions 1100 and 1200 described with reference to FIGS. 22 and 23 may correspond to one or a plurality of cell blocks.

Referring to FIG. 22, the core region 1100 may include a first region 1110 and a second region 1120. In the first region 1110, a row decoder 1111, a sub-wordline decoder 1112, and a wordline contacts 1113 may be disposed, and in the second region 1120, a sense amplifier circuit 1121 and a bitline contacts 1122 may be disposed.

When the core region 1110 corresponds to a cell block, a remaining free area may be present as the core region 1110 and the cell block are stacked. As illustrated in FIG. 22, in one or more embodiments, a computation circuit 1130 may be disposed in the free area of the core region 1110. The computation circuit 1130 may include a circuit configured to execute computation based on read data read from the memory cells of the cell block, input data received from an external entity, or the like.

In FIG. 22, wordline contacts 1113 may be disposed in the first region 1110, and bitline contacts 1122 may be disposed in the second region 1120. A substrate for implementing the core region 1100 may include a first surface on which elements may be formed, and a second surface opposing the first surface, and in the example embodiment illustrated in FIG. 22, the core region 1100 and the cell block may be stacked such that the second surface may be positioned in vicinity of the cell block rather than the first surface. Accordingly, wordline contacts 1113 and bitline contacts 1122 penetrating a substrate of the core region 1100 may be formed.

Thereafter, referring to FIG. 23, the core region 1200 may include a first region 1210 in which the row decoder 1211 and the sub-wordline decoder 1212 are disposed, and a second region in which the sense amplifier circuit 1220 is disposed. In a free area not occupied by the row decoder 1211, the sub-wordline decoder 1212, and the sense amplifier circuit 1220, the computation circuits 1230 and 1240 may be disposed.

In FIG. 23, a substrate for implementing the core region 1200 may include a first surface on which elements may be formed, and a second surface opposing the first surface, and the core region 1200 and the cell block may be stacked such that the first surface may be positioned in vicinity of the cell block rather than the second surface. Accordingly, the core region 1200 and the cell block may be electrically connected without wordline contacts and bitline contacts penetrating the substrate of the core region 1200. By disposing the computation circuits 1230, 1240 in the additionally ensured free area obtained by not providing the wordline contacts and bitline contacts, complex or diverse computations may be executed in the semiconductor device.

In the embodiments described with reference to FIGS. 22 and 23, the core region 1100, 1200 may have a windmill structure. In the cell blocks stacked with the core regions 1100 and 1200, bitlines connected to the memory cells may extend in the second direction (X-axis direction), and wordlines may extend in the third direction (Y-axis direction).

When the core regions 1100 and 1200 correspond to a plurality of cell blocks, the number of cell blocks may be four in one or more embodiments. For example, in the example embodiment illustrated in FIG. 22, a first cell block may be disposed below a ¼ region positioned on an upper left end of the core region 1100, and a second cell block may be disposed below a ¼ region positioned on an upper right end of the core region 1100. A third cell block may be disposed below a ¼ region positioned on a lower left end of the core region 1100, and a fourth cell block may be disposed below a ¼ region positioned on a lower right end of the core region 1100.

The memory cells of the first cell block may be controlled by the sense amplifier circuit 1121 disposed on the upper left end of the core region 1100 and the sub-wordline decoder 1112 disposed on the upper right end of the core region 1100. The sense amplifier circuit 1121 disposed on the upper left end of the core region 1100 may be connected to the memory cells of the first cell block and the memory cells of the third cell block. For example, in operations such as read and write operations for the first cell block, the sense amplifier circuit 1121 may use a bitline connected to the memory cells of the first cell block as a bitline and may use the bitline connected to the memory cells of the third cell block as a complementary bitline.

The memory cells of the second cell block may be controlled by the sense amplifier circuit 1121 disposed on the lower right end of the core region 1100 and the sub-wordline decoder 1112 disposed on the upper right end of the core region 1100. The sense amplifier circuit 1121 disposed on the lower right end of the core region 1100 may be connected to the memory cells of the second cell block and the memory cells of the fourth cell block. For example, in operations such as read and write operations for the second cell block, the sense amplifier circuit 1121 may use a bitline connected to the memory cells of the second cell block as a bitline and may use a bitline connected to the memory cells of the fourth cell block as a complementary bitline.

According to one or more embodiments, a semiconductor device may be implemented with a structure in which a first layer on which memory cells are disposed, a second layer on which circuits for driving the memory cells are disposed, and a third layer on which an input/output interface and a logic circuit are disposed are stacked, and a computation block for computation may be added to at least one of the second layer and the third layer. By stacking the second layer and the third layer, each implementing a core region and a peripheral circuit region having relatively small areas, on the first layer implementing a cell region having a relatively large area, a region in which the computation block is disposed may be ensured sufficiently. Since AI computation may be executed in the semiconductor device and only the result thereof may be returned to an external device, a semiconductor device which may reduce an increase in bandwidth and may be optimized for implementing AI computation may be implemented.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device, comprising:
a first layer comprising memory cells connected to bitlines and wordlines, wherein each of the memory cells comprises a cell transistor and a cell capacitor;
a second layer on the first layer, the second layer comprising a row decoder connected to the wordlines, a sense amplifier circuit connected to the bitlines, and a column decoder configured to determine a select bitline among the bitlines; and
a third layer on the second layer, the third layer comprising:
a logic circuit configured to control the row decoder, the sense amplifier circuit, and the column decoder, and
an input/output interface configured to transmit a signal to and receive a signal from an external device,
wherein the second layer comprises a computation circuit configured to execute at least one computation based on at least one of input data received by the input/output interface and read data read from the memory cells.

2. The semiconductor device of claim 1,
wherein the second layer comprises a first process in memory (PIM) block, and
wherein the third layer comprises a second PIM block.

3. The semiconductor device of claim 1, wherein the third layer further comprises a static random access memory (SRAM) cell array comprising SRAM cells.

4. The semiconductor device of claim 1, wherein a first bonding structure on a first boundary on which the first layer is coupled to the second layer is different from a second bonding structure on a second boundary on which the second layer is coupled to the third layer.

5. The semiconductor device of claim 1, wherein the computation circuit is adjacent to at least one of the row decoder and the sense amplifier circuit in a second direction perpendicular to a first direction in which the first layer, the second layer and the third layer are stacked.

6. The semiconductor device of claim 1, wherein the second layer further comprises a bitline contact region comprising bitline contact structures connected to the bitlines, and a wordline contact region comprising wordline contact structures connected to the wordlines.

7. The semiconductor device of claim 1, wherein the first layer further comprises a first substrate and a first interconnection region on the first substrate,
wherein the second layer further comprises a second substrate and a second interconnection region on the second substrate, and
wherein the third layer further comprises a third substrate, a third upper interconnection region on a first surface of the third substrate, and a third lower interconnection region on a second surface of the third substrate.

8. The semiconductor device of claim 7, wherein the second interconnection region comprises a second upper interconnection region on a first surface of the second substrate, and a second lower interconnection region on a second surface of the second substrate, and
wherein a first interconnection that is farthest from the first substrate in the first interconnection region is bonded to a second interconnection that is farthest from the first surface of the second substrate in the second upper interconnection region on a first boundary between the first layer and the second layer.

9. The semiconductor device of claim 8, wherein a third interconnection that is farthest from the second surface of the second substrate in the second lower interconnection region is bonded to a fourth interconnection that is farthest from the first surface of the third substrate in the third upper interconnection region on a second boundary between the second layer and the third layer, and
wherein the third lower interconnection region comprises at least one input/output pad.

10. The semiconductor device of claim 8,
wherein a fifth interconnection that is farthest from the second surface of the second substrate in the second lower interconnection region is bonded to a sixth interconnection that is farthest from the first surface of the third substrate in the third lower interconnection region on a second boundary between the second layer and the third layer, and
wherein the third upper interconnection region comprises at least one input/output pad.

11. The semiconductor device of claim 7, wherein the second layer further comprises a second via structure penetrating the second substrate, and
wherein the second via structure is connected to the second interconnection region and a landing pad of the first layer.

12. The semiconductor device of claim 11, wherein a seventh interconnection that is farthest from the second substrate in the second interconnection region is bonded to an eighth interconnection that is farthest from the first surface of the third substrate in the third upper interconnection region on a second boundary between the second layer and the third layer, and
wherein the third lower interconnection region comprises at least one input/output pad.

13. The semiconductor device of claim 11, wherein a ninth interconnection that is farthest from the second substrate in the second interconnection region is bonded to a tenth interconnection that is farthest from the second surface of the third substrate in the third lower interconnection region on a second boundary between the second layer and the third layer, and
wherein the third upper interconnection region comprises at least one input/output pad.

14. A semiconductor device, further comprising:
a first layer comprising memory cells connected to bitlines and wordlines;
a second layer comprising a sub-wordline decoder connected to the wordlines, a sense amplifier circuit connected to the bitlines, and a column decoder configured to determine a select bitline among the bitlines; and
a third layer comprising a peripheral circuit configured to control the sense amplifier circuit and the column decoder,
wherein the first layer, the second layer, and the third layer are stacked sequentially in a first direction,
wherein the second layer comprises a computation circuit configured to execute computation using read data read from the memory cells,
wherein the bitlines extend in a second direction perpendicular to the first direction, and the wordlines extend in a third direction perpendicular to the first direction and the second direction, and
wherein the computation circuit is adjacent to the sense amplifier circuit in the second direction, and adjacent to the sub-wordline decoder in the third direction.

15. The semiconductor device of claim 14, wherein a first boundary on which the first layer is coupled to the second layer has a bonding structure in which a first interconnection in the first layer and that is closest to the second layer is coupled to a second interconnection in the second layer and that is closest to the first layer, and
wherein a first bonding insulating layer of the first layer is coupled to a second bonding insulating layer of the second layer.

16. The semiconductor device of claim 14, wherein a second boundary on which the second layer is coupled to the third layer has a bonding structure in which a second interconnection in the second layer and that is closest to the third layer is coupled to a third interconnection in the third layer and that is closest to the second layer, and
wherein a second bonding insulating layer of the second layer is coupled to a third bonding insulating layer of the third layer.

17. The semiconductor device of claim 14, wherein a first boundary on which the first layer is coupled to the second layer has a bonding structure in which a first bonding insulating layer of the first layer is coupled to a second bonding insulating layer of the second layer, and
wherein the semiconductor device further comprises a second via structure penetrating the first bonding insulating layer and the second bonding insulating layer.

18. The semiconductor device of claim 14, wherein a second boundary on which the second layer is coupled to the third layer has a bonding structure in which a second bonding insulating layer of the second layer is coupled to a third bonding insulating layer of the third layer, and
wherein the semiconductor device further comprises a third via structure penetrating the second bonding insulating layer and the third bonding insulating layer.

19. A semiconductor device, comprising:
a first layer comprising memory cells;
a second layer coupled to the first layer on a first boundary, the second layer comprising a core circuit configured to control the memory cells; and
a third layer coupled to the second layer on a second boundary, the third layer comprising a peripheral circuit configured to control the core circuit,
wherein a first bonding insulating layer in the first layer is coupled to a second bonding insulating layer in the second layer on the first boundary,
wherein a third bonding insulating layer in the second layer is coupled to a fourth bonding insulating layer in the third layer on the second boundary,
wherein the first boundary has one of a first bonding structure in which interconnections opposing each other are coupled to and electrically connected to each other, and a second bonding structure in which at least one via structure penetrates the first bonding insulating layer and the second bonding insulating layer, and
wherein the second boundary has one of the first bonding structure and the second bonding structure.

20. The semiconductor device of claim 19, wherein each of the first, second, third and fourth bonding insulating layers comprises at least one of silicon oxide and silicon carbon nitride.
